(19) United States
(12) Patent Application Publication
(10) Pub. No.: US 2001/0045663 A1
(43) Pub. Date: Nov. 29, 2001

(54) Semiconductor circuit device and method for manufacturing thereof

(76) Inventors: Tomohiko Edura, Tokyo (JP); Junichi Suzuki, Tokyo (JP)

Correspondence Address: Pillsbury Winthrop LLP, Intellectual Property Group, Ninth Floor, 1100 New York Avenue, NW, Washington, DC, 20005-3918, US

(21) Appl. No.: 09/851,987

(22) Filed: May 10, 2001

(30) Foreign Application Priority Data
May 19, 2000 (JP) 2000-148044

(51) Int. Cl. H01L 23/48; H01L 21/46

(52) U.S. Cl. 257/773; 438/460

(57) ABSTRACT

A semiconductor circuit device includes: a substrate; a semiconductor circuit formed on an upper surface of the substrate; a connecting part that is formed on a side face of the substrate, and the connecting part electrically connecting to the semiconductor circuit.

This patent application claims priority from Japanese patent application No. 2000-148044 filed on May 19, 2000, the contents of which are incorporated herein by reference.

### BACKGROUND OF THE INVENTION

1. Field of the Invention

The present invention relates to a semiconductor circuit device having a semiconductor circuit. In particular, the present invention relates to a semiconductor circuit device and the method of manufacturing a semiconductor circuit device that has a connecting part, which is electrically connected to the semiconductor circuit included in the semiconductor circuit device.

2. Description of the Related Art

Recently, research and development has been actively undertaken in the field of highly integrated semiconductor circuit devices. However, the reduction of the size of a device and a wiring of a semiconductor circuit has nearly reached the limits. Therefore, it is required to increase the area of the circuit within the area of substrate.

FIG. 1 shows a top view of a conventional semiconductor circuit device 20. The semiconductor circuit device 20 has a connecting part 40, a wiring 50, and a semiconductor circuit 60 on an upper surface of a substrate 74. The semiconductor circuit 60 is electrically connected to the connecting part 40 by the wiring 50, which is made of material such as aluminum.

The connecting part 40 and the semiconductor circuit 60 are provided on the same upper surface of the substrate 74 of the semiconductor circuit device 20 as shown in FIG. 1. Therefore, it is difficult to increase the ratio of the area occupied by a semiconductor circuit to the whole area of the semiconductor circuit device 20. Furthermore, a gold wire is used for connecting the connecting part 40 to a conductor outside the semiconductor circuit device 20. A parasitic component such as a capacitance contained in the gold wire causes the loss of electricity, and therefore makes the electronic design of the semiconductor circuit device difficult.

### SUMMARY OF THE INVENTION

Therefore, it is an object of the present invention to provide a semiconductor circuit device and a method for manufacturing thereof, which is capable of overcoming the above drawbacks accompanying the conventional art. The above and other objects can be achieved by combinations described in the independent claims. The dependent claims define further advantageous and exemplary combinations of the present invention.

According to the first aspect of the present invention, a semiconductor circuit device comprises: a substrate; a semiconductor circuit formed on an upper surface of the substrate; and a connecting part that is formed on a side face of the substrate, and the connecting part electrically connecting to the semiconductor circuit.

The connecting part may have an upper part on said upper surface of said substrate. The upper part of the connecting part may be electrically connected to the semiconductor circuit. The connecting part may have a lower part formed on a notch that is formed in the side face of the substrate. The connecting part may further have an upper part on the upper surface of the substrate; and the upper part of the connecting part may be electrically connected to the lower part of the connecting part.

The lower part may be formed all over the surface of the notch. The lower part may be formed on a part of a surface of the notch. The lower part may be formed all over a bottom surface of the upper part that faces the substrate. The notch may be formed on the side face of the substrate from a bottom surface through a top surface of the substrate.

The upper part of the connecting part may be formed by a material that is different to a material that forms the lower part of the connecting part. The connecting part may be formed on a plurality of side faces of the substrate. A plurality of the connecting parts may be formed on the side face of the substrate at a predetermined interval. The lower part of the connecting part may be formed by gold.

The connecting part of the semiconductor circuit device may be electrically connected to another connecting part that is formed on a side face of another semiconductor circuit device. The notch may have a half-cylindrical shape. The notch may have a half-conical shape. The area of the upper part may be larger than the area of the lower part that contacts with the upper part.

According to the second aspect of the present invention, a semiconductor circuit device comprises a first semiconductor circuit device that includes a first substrate; a first semiconductor circuit formed on an upper surface of the first substrate; and a first connecting part that is formed on a side face of the first substrate, and the first connecting part electrically connecting to the first semiconductor circuit; and a second semiconductor circuit device that includes: a second substrate; a second semiconductor circuit formed on an upper surface of the second substrate; and a second connecting part that is formed on a side face of the second substrate, and the second connecting part electrically connecting to the second semiconductor circuit; wherein: the first connecting part and the second connecting part are electrically connected to each other.

The side face of the first substrate of the first semiconductor circuit device and the side face of the second substrate of the second semiconductor circuit device may be contacted with each other so that the first connecting part and the second connecting part are electrically connected to each other.

The first connecting part may be formed on a first notch provided in the side face of the first substrate; and the second connecting part may be formed on a second notch provided in the side face of the second substrate; and the first notch and the second notch may be filled by a conductive material when the first connecting part and said second connecting part are contacted with each other.

The first substrate may have a concave part, in which the second semiconductor circuit device is installed, and the first connecting part is formed on a side face of the concave part; and the first connecting part of the first semiconductor circuit device and the second connecting part of the second semiconductor circuit device may be electrically connected to each other.

According to the third aspect of the present invention, a method for manufacturing a semiconductor circuit device comprises: a step of forming a first connecting part on an upper surface of a substrate; a step of forming a hole from a bottom surface through the upper surface of the substrate so that one of the ends of the hole that faces the upper surface is covered by the first connecting part; a step of forming a second connecting part by forming a conductive material on a surface of the hole and a bottom surface of the first connecting part that faces the hole; and a step of cutting the substrate so that a part of said first connecting part and said second connecting part is exposed along a cutting face of said substrate.

The step of forming the hole may form the hole in a half-cylindrical shape. The step of forming the hole may form the hole in a half-conical shape. The step of forming the first connecting part may form the first connecting part so that the area of the first connecting part becomes larger than the area of the second connecting part that contacts with the first connecting part.

The summary of the invention does not necessarily describe all necessary features of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a top view of a conventional semiconductor circuit device 20.

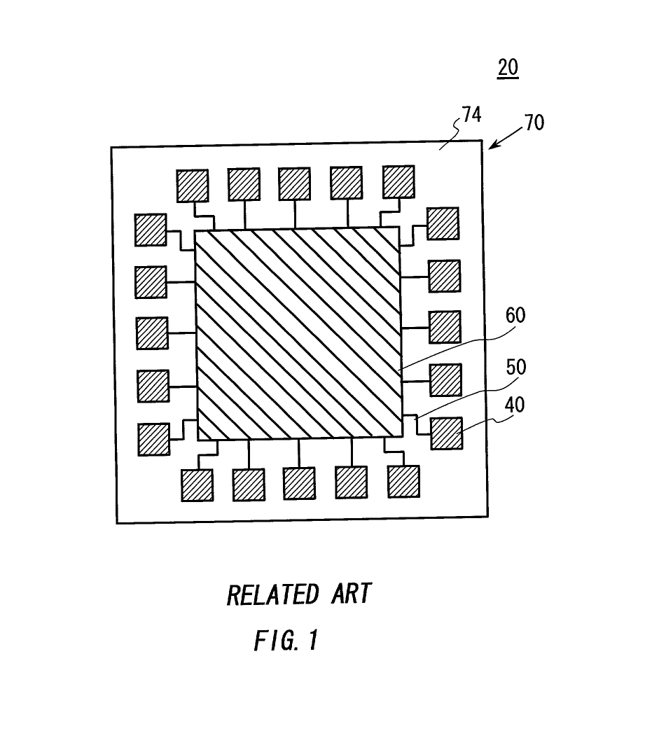

FIG. 2 shows a top view of a semiconductor circuit device 10 of an embodiment of the present invention.

FIG. 3A and 3B show a configuration of the connecting part 30 formed on the side face 72a of the substrate 70.

FIG. 4 shows another embodiment of the configuration of the connecting part 30.

FIG. 5A and 5B show other embodiments of the configuration of the connecting part 30.

FIG. 6 shows a configuration of the composite semiconductor circuit device 100 having a plurality of semiconductor circuit devices 10a, 10b, 10c, and 10d.

FIG. 7A and 7B show a plan view of the configuration of another embodiment of a composite semiconductor circuit device.

FIG. 8A and 8B show cross sections of the connecting part 30a and 30b.

FIG. 9A-9E shows a process of manufacturing the semiconductor circuit device 10 shown in FIG. 2 and FIG. 3.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

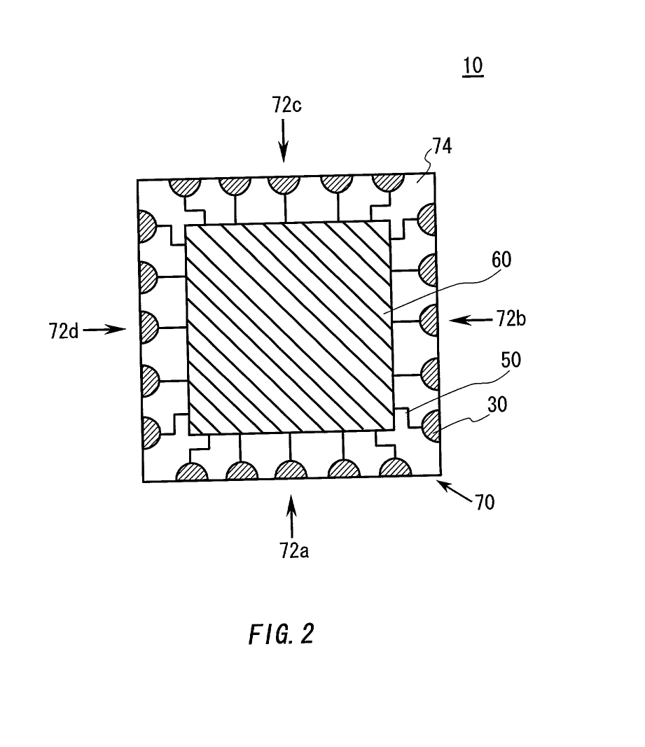

FIG. 2 shows a top view of a semiconductor circuit device 10 of an embodiment of the present invention. The semiconductor circuit device 10 has a substrate 70, a semiconductor circuit 60, a connecting part 30, and a wiring 50. The semiconductor circuit 60 is formed on the upper surface 74 of the substrate 70. The connecting part 30 is formed on the side faces 72a, 72b, 72c, and 72d of the substrate 70. The connecting part 30 is electrically connected to a semiconductor element contained in the semiconductor circuit 60 by the wiring 50, which is made of material such as aluminum.

The connecting part 30 is preferably provided on one side face or a plurality of side faces of the substrate 70. In the present embodiment, the connecting part 30 is formed on a plurality of the side faces 72a, 72b, 72c, and 72d of the substrate 70.

Furthermore, a plurality of the connecting parts 30 is formed on each of the side faces of the substrate 70 at a predetermined interval that is determined desirably. For example, the connecting part 30 maybe arranged on the side faces 72 of substrate 70 at a constant interval from the side face 72a to side face 72d as shown in FIG. 2. Moreover, the connecting part 30 may be arranged on the side faces 72a-72d of the substrate 70 at different intervals for each of the side faces 72a-72d.

Preferably the connecting parts 30 are arranged on the side faces of the substrate 70 so that the connecting parts 30 provided on each of the side faces of the two different substrates 70 of two different semiconductor circuit devices 10 are contacted with each other when each side face of the two different semiconductor circuit devices 10 are contacted with each other.

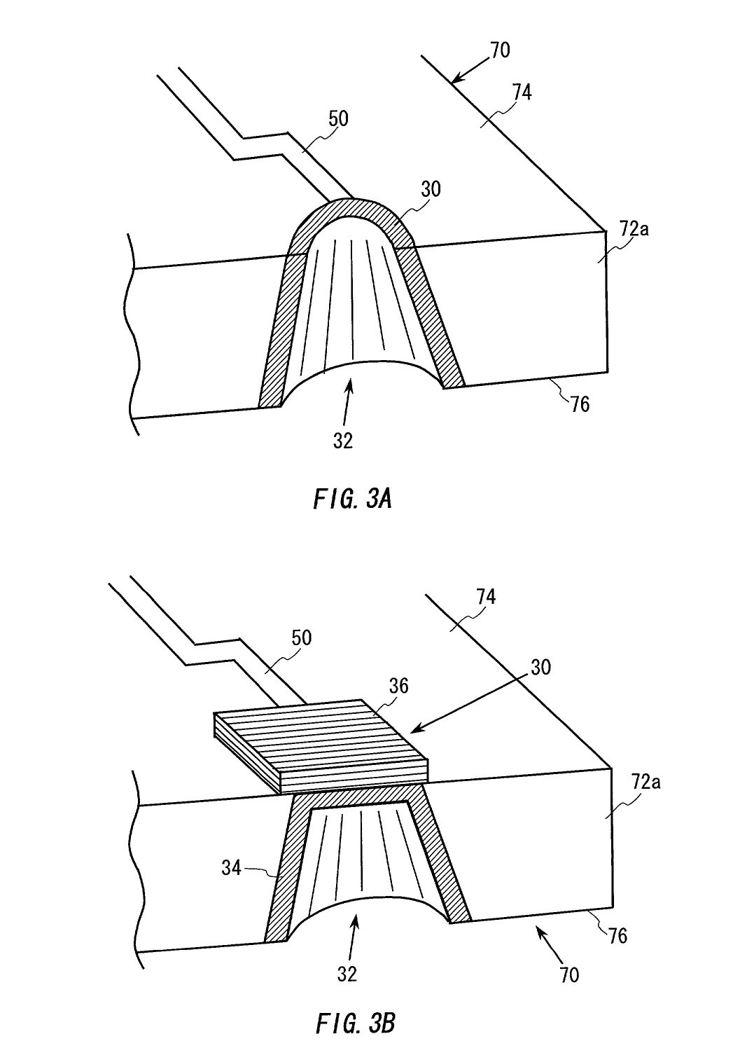

FIG. 3 shows a configuration of the connecting part 30 formed on the side face 72a of the substrate 70.

FIG. 3A shows an embodiment of the configuration of the connecting part 30 formed on the side face 72a of the substrate 70. In this example, notch 32 is formed on the side face 72a of the substrate 70. The notch 32 is preferably formed by cutting through the side face of the substrate 72 from the upper surface 74 to the bottom surface 76 of the substrate 70.

In another embodiment, the notch 32 may be formed by cutting the side face 72 of the substrate 70 from the upper surface 74 to a position between the upper surface 74 and the bottom surface 76 of the substrate 70. Also, the notch 32 may be formed by cutting the side face 72 of the substrate 70 from the bottom surface 76 to a position between the upper surface 74 and the bottom surface 76 of the substrate 70. Moreover, the notch 32 may be formed by cutting the side face 72a of the substrate 70 from a first position between the upper surface 74 and the bottom surface 76 of the substrate 70 to a second position between the upper surface 74 and bottom surface 76 of the substrate 70.

The notch 32 may have a half-cylindrical shape or half-conical shape. Moreover, the notch 32 may have a polygonal shape or polygonal cone shape.

As shown in FIG. 3A, the upper surface of the connecting part 30 is exposed on the upper surface 74 of the substrate 70. Also, the wiring 50 is electrically connected to the upper surface of the connecting part 30. However, the wiring 50 may be electrically connected to the region between the upper surface and the bottom surface of the connecting part 30 inside the substrate 70. Furthermore, the wiring 50 may be electrically connected to the bottom surface of the connecting part 30.

In FIG. 3A, the connecting part 30 is formed by plating conductive material all over the surface of the notch 32. The connecting part 30 is formed by a conductive material such as gold. In another embodiment, the connecting part 30 may be formed by filling a conductive material inside the notch 32.

FIG. 3B shows another embodiment of the configuration of the connecting part 30 formed on the side face 72a of the substrate 70. In this embodiment, the notch 32 is formed on the side face 72a of the substrate 70. The notch 32 has a half-conical shape in FIG. 3B. However, the notch 32 may have a half-cylindrical shape. Moreover, the notch 32 may have a polygonal shape or polygonal cone shape.

The connecting part 30 has an upper part 36 and a lower part 34. The upper part 36 is formed on the upper surface 74 of the substrate 70. The lower part 34 is formed on the notch 32 that is formed on the side face 72a of the substrate 70. The upper part 36 of the connecting part 30 is electrically connected to the lower part 34 of the connecting part 30. Specifically, the upper part 36 of the connecting part 30 is electrically connected to the top surface of the lower part 34 of the connecting part 30. The area of the upper part 36 is larger than the area of the upper surface of the lower part 34 that contacts with the upper part 36.

By providing the upper part 36 on the lower part 34, the connecting part 30 can be reliably connected to the wiring 50. Thereby, the connecting part 30 can be reliably connected to the semiconductor circuit 60 electrically.

The wiring 50 is electrically connected to the upper part 36 of the connecting part 30. The upper part 36 of the connecting part 30 is electrically connected to a semiconductor element contained in the semiconductor circuit 60 as shown in FIG. 2 by the wiring 50.

In FIG. 3B, a lower part 34 of the connecting part 30 is formed by plating conductive material all over the surface of the notch 32 and all over the bottom surface of the upper part 36 that faces to the lower part 34.

In the other embodiment, the lower part 34 may be formed by filling conductive material in the notch 32. The lower part 34 of the connecting part 30 is formed by a conductive material such as gold. The upper part 36 of the connecting part 30 is also formed by a conductive material. The upper part 36 may be formed by a material that is different from the material of the lower part 34. The upper part 36 may also be formed by a material that is the same as the material of the lower part 34.

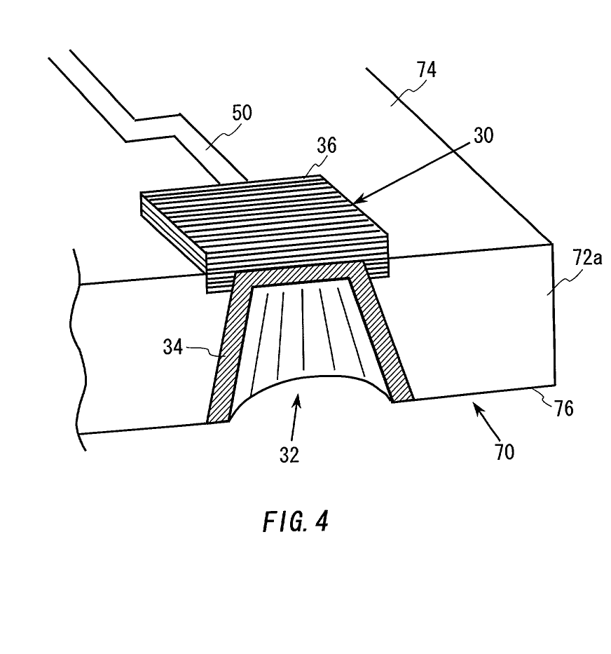

FIG. 4 shows other embodiments of the configuration of the connecting part 30. In FIG. 4, the upper part 36 of the connecting part 30 contacts both the upper surface and side face of the lower part 34 of the connecting part 30. The configuration except the configuration of the upper part 36 is the same as the configuration shown in FIG. 3B.

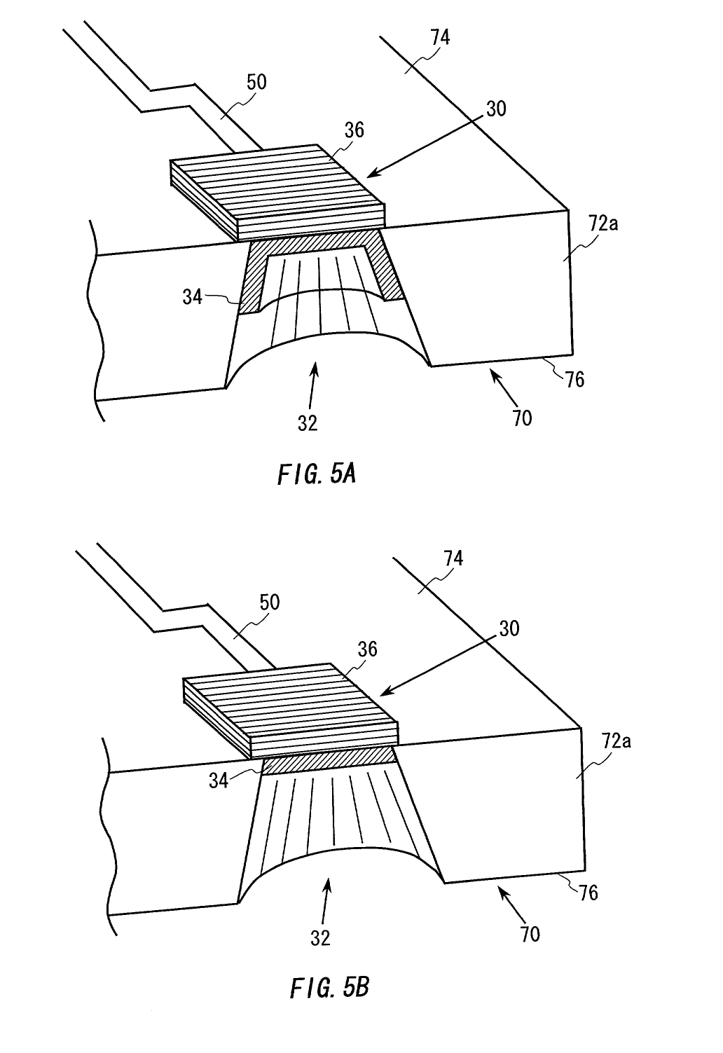

FIG. 5A and 5B show other embodiments of the configuration of the connecting part 30. In FIG. 5A, the connecting part 30 is formed on a part of the surface of the notch 32. In FIG. 5B, the lower part 34 of the connecting part 30 is formed all over the bottom surface of the upper part 36 that faces the lower part 34. However, the lower part 34 of the connecting part 30 may be formed on a part of the bottom surface of the upper part 36 that faces the lower part 34. The configuration except the configuration of the lower part 34 is the same as the configuration shown in FIG. 3B.

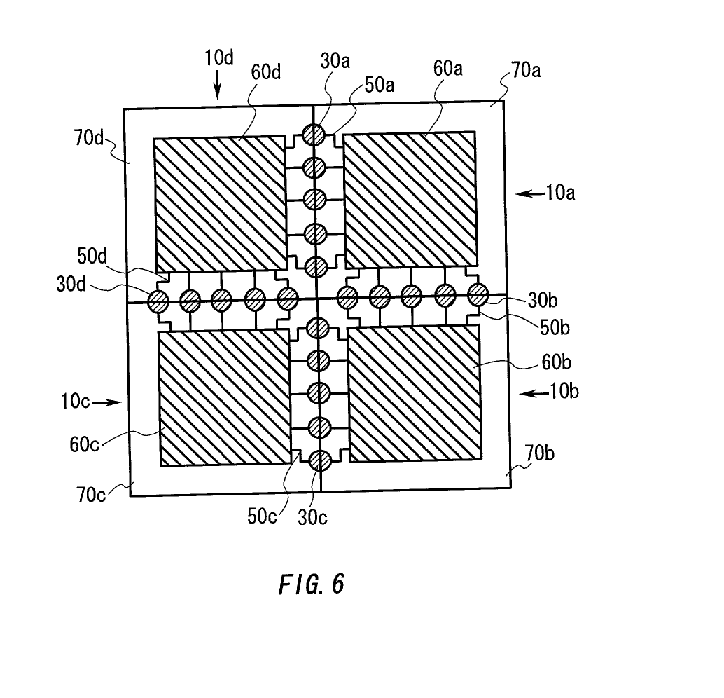

FIG. 6 shows a configuration of the composite semiconductor circuit device 100 having a plurality of semiconductor circuit devices 10a, 10b, 10c, and 10d. Each of the semiconductor circuit devices 10a, 10b, 10c, and 10d have connecting parts 30a, 30b, 30d, and 30d, respectively on the side faces of each of the substrates 70a, 70b, 70c, and 70d. The connecting parts 30a-30d may have a configuration of one of the configurations described from FIG. 3 to FIG. 5.

The semiconductor circuit device 10a has a semiconductor circuit 60a on an upper surface of the substrate 70a and a connecting part 30a on two side faces of the substrate 70a. The semiconductor element included in the semiconductor circuit 60a is electrically connected to the connecting part 30a by a wiring 50a.

The semiconductor circuit devices 10b, 10c, and 10d have a same configuration with the configuration of the semiconductor circuit device 10a. The semiconductor circuit device 10a-10d preferably has a same, or similar, configuration with the semiconductor circuit device 10 that is described in FIG. 2. In FIG. 6, the composite semiconductor circuit device 100 has four semiconductor circuit devices 10a-10d. However, the composite semiconductor circuit device 100 may have two semiconductor circuit devices 10 or more as other embodiments.

The side faces of each of the semiconductor circuit devices 10a, 10b, 10c, and 10d, which are next to each other, are contacted with each other. Thereby, the semiconductor circuit devices 10a, 10b, 10c, and 10d that are next to each other are connected to each other electrically by each of the connecting parts 30a-30d. For example, the connecting part 30a of the semiconductor circuit device 10a is electrically connected to the connecting part 30b of the semiconductor circuit device 10b in FIG. 6. Furthermore, the connecting part 30a of the semiconductor circuit device 10a is electrically connected to the connecting part 30d of the semiconductor circuit device 10d. However, all the semiconductor circuit devices 10a, 10b, 10c, and 10d next to each other are not necessarily connected to each other electrically.

Each of the semiconductor circuit devices 10a-10d preferably has the same shape. However, the composite semiconductor circuit device 100 may have semiconductor circuit devices 10a-10d having different shapes with each other.

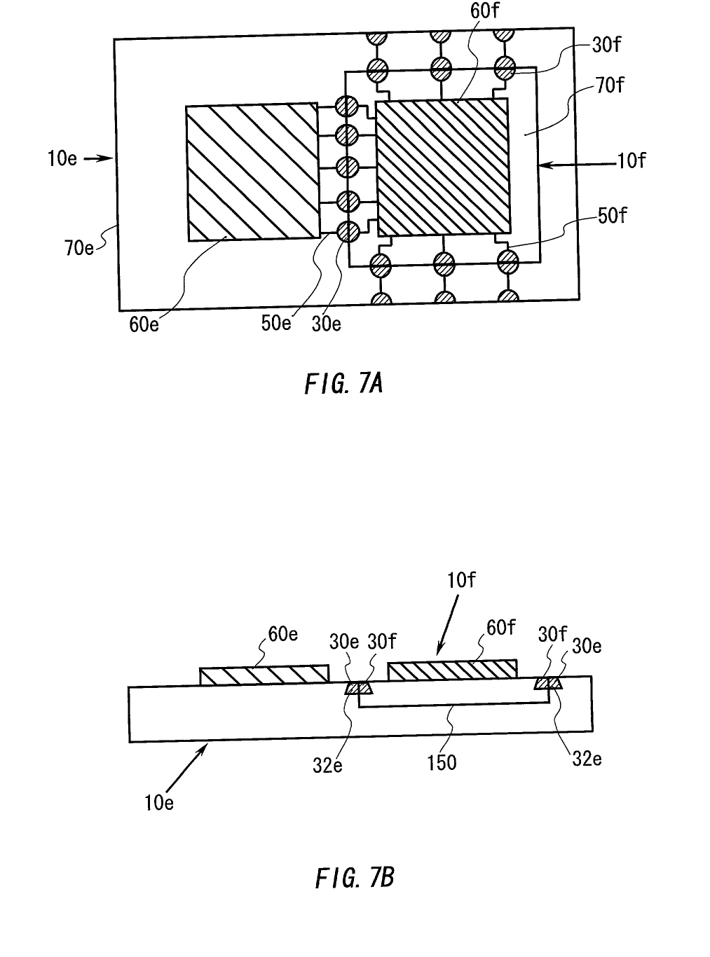

FIG. 7A shows a plan view of the configuration of another embodiment of a composite semiconductor circuit device 100 having a semiconductor circuit device 10e and 10f. FIG. 7B shows a cross sectional view of the configuration of a composite semiconductor circuit device 100. The semiconductor circuit device 10e has connecting parts 30e. The semiconductor circuit device 10f has connecting parts 30f. The connecting parts 30e and 30f may have a configuration of one of the configurations described from FIG. 3 to FIG. 5.

As shown in FIG. 7B, the semiconductor circuit device 10e has a notch 32e and a concave part 150 on its upper surface. The semiconductor circuit device 10f is provided inside the concave part 150 of the semiconductor circuit device 10e.

The semiconductor circuit device 10e has a semiconductor circuit 60e on an upper surface of a substrate 70e and a connecting part 30e on a side face of the substrate 70e. The semiconductor element contained in the semiconductor circuit 60e and the connecting part 30e are connected electrically with each other by the wiring 50e. The connecting part 30e of the semiconductor circuit device 10e and the connecting part 30f of the semiconductor circuit device 10f are connected electrically with each other. Furthermore, each of the side faces of the semiconductor circuit device 10e and 10f are contacted with each other.

In FIG. 7A and 7B, the composite semiconductor circuit device 100 has two semiconductor circuit devices 10e and 10f. However, the composite semiconductor circuit device 100 may have three semiconductor circuit devices 10 or more, and each of the semiconductor circuit apparatuses 10 have connecting parts 30 on its side faces. For example, the semiconductor circuit device 10e may have a plurality of concave parts on the upper surface, and the semiconductor circuit devices 10f having connecting parts on its side faces may be provided inside each concave part of the semiconductor circuit device 10e.

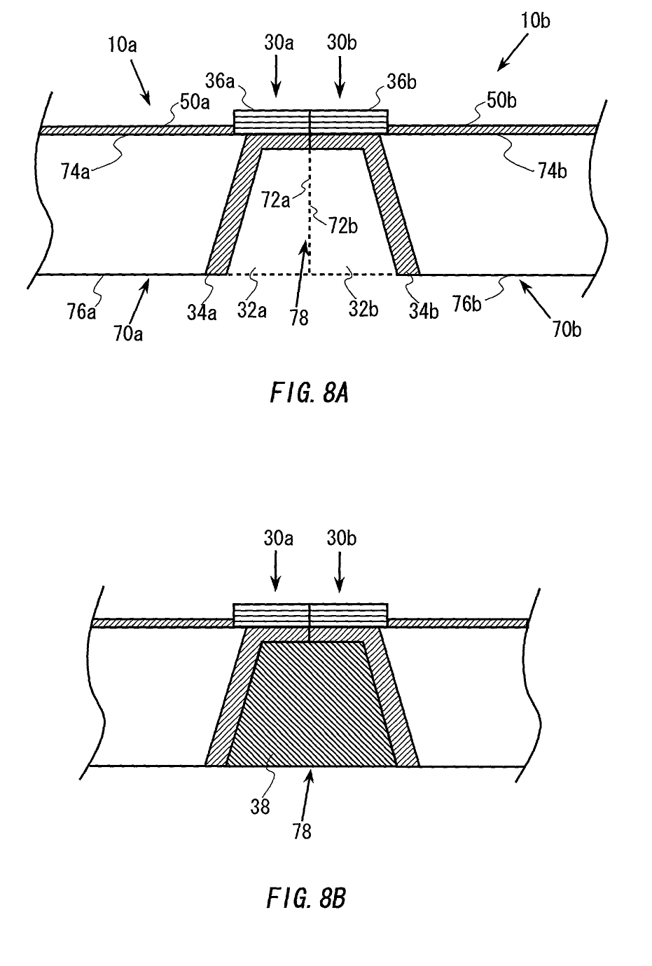

FIG. 8A and FIG. 8B show cross sections of the connecting part 30a and 30b that are connected electrically with each other when the side faces of each of the semiconductor circuit device 10a and the semiconductor circuit device 10b are contacted with each other.

FIG. 8A shows a cross sectional view of a configuration of the connecting part 30a and 30b that are contacted with each other. The connecting part 30a and the connecting part 30b have a same configuration with the configuration of the connecting part 30 explained in FIG. 3B.

The upper part 36a of the connecting part 30a is formed on the upper surface 74a of the substrate 70a. The upper part 36a is electrically connected to the semiconductor element contained in the semiconductor circuit 60a (not shown in figure) by the wiring 50a. Similarly, the upper part 36b of the connecting part 30b is formed on the upper surface 74b of the substrate 70b. The upper part 36b is electrically connected to the semiconductor element contained in the semiconductor circuit 60b (not shown in figure) by the wiring 50b. The lower part 34a of the connecting part 30a and the lower part 34b of the connecting part 30b are formed on the notch 32a and the notch 32b that are formed on the side faces of each of the substrate 70a and 70b.

In FIG. 8A and 8B, the side faces 72a and 72b of each of the substrates 70a and 70b are contacted with each other. Thereby, the connecting parts 30a and 30b are electrically connected to each other. Specifically, the side face of the upper part 36a of the connecting part 30a and the side face of the upper part 36b of the connecting part 30b are contacted with each other and electrically connected to each other.

Furthermore, a part of the lower part 34a, which positions at the same face with the side face of the connecting part 30a, and a part of the lower part 34b, which positions at the same face with the side face of the connecting part 30b, are contacted with each other and electrically connected to each other. Both the upper part 36a and 36b and the lower part 34a and 34b are preferably contacted with each other and electrically connected to each other. However, any one of the combinations of the upper parts 36a and 36b or the lower parts 34a and 34b may be contacted with each other and electrically connected to each other.

A hole portion 78 is formed on the bottom surfaces 76a and 76b of the substrates 70a and 70b by the notches 32a and 32b. The hole portion 78 is covered by the lower part 34a and the lower part 34b.

FIG. 8B shows a cross sectional view of another embodiment of the configuration of the connecting parts 30a and 30b. A conductive material 38 is filled all over the hole portion 78 that is formed by the notch 32a and notch 32b of the connecting part 30a and 30b. However, material other than the conductive material may be filled in the hole portion 78.

Furthermore, the conductive material 38 is preferably filled all over the hole portion 78 as shown in FIG. 8B. However, the conductive material 38 may be filled in a part of the hole portion 78. By filling the hole portion 78 with the conductive material 38, a mechanical reliability and an electrical reliability of the connecting parts 30a and 30b can be increased.

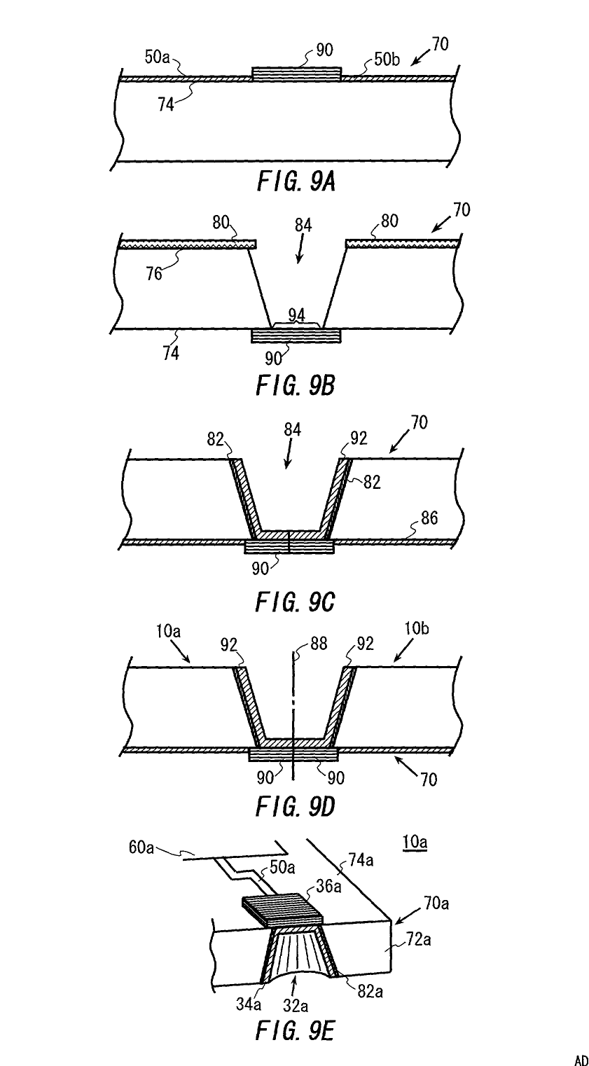

FIG. 9A-9E shows a process of manufacturing the semiconductor circuit device 10 shown in FIG. 2 and FIG. 3.

As shown in FIG. 9A, a first connecting part 90 is formed on the upper surface 74 of the substrate 70. The first connecting part 90 is formed by a conductive material such as aluminum. Furthermore, the first connecting part 90 is connected to the semiconductor element contained in the semiconductor circuit (not shown in figure) that is formed on the upper surface 74 of the substrate 70 by the wiring 50a and 50b. The wiring 50a and 50b are formed on the upper surface 74 of the substrate 70.

Next, the substrate 70 is turned upside down as shown in FIG. 9B. Then, a hole 84 is formed by etching the substrate 70 from the bottom surface 76 to the upper surface 74 until a part of the bottom surface 94 of the first connecting part 90 is exposed. Because the first connecting part 90 is formed on the upper surface 74 of the substrate 70, the bottom end of the hole 84 is covered by the first connecting part 90. Preferably, a resist layer 80 is previously formed on the bottom surface 76 of the substrate 70 except the region that is to be the hole 84 by etching. Wet etching is used for forming a hole 84 of FIG. 9. However, dry etching may also be used for forming the hole 84.

Next, as shown in FIG. 9C, an oxidizing film 82 is formed on the surface of the hole 84. Then, a second connecting part 92 is formed by attaching a conductive material such as gold to the surface of the hole 84 and the back surface 94 of the first connecting part 90 by such as the method of plating. In the present embodiment, the second connecting part 92 is formed on the surface of the oxidizing film 82, which is formed on the sidewall of the etched region of the substrate 70, and the bottom surface 94 of the first connecting part 90. The oxidizing film 82 is preferably formed such that the conductive material such as gold does not enter inside the substrate 70. Then, the resist layer 80 shown in FIG. 9B is removed from the bottom surface 76 of the substrate 70.

Next, as shown in FIG. 9D, the substrate 70 is cut along the cutting line 88 so as to be divided into the semiconductor circuit devices 10a and 10b. The cutting line 88 is preferably drawn to substantially cross the center of the hole 84. As a result, the first connecting part 90 and the second connecting part 92 are exposed at the cutting face, which is formed by cutting the substrate 70 along the cutting line 88. By the above process, the semiconductor circuit devices 10a and 10b having connecting parts 30a and 30b explained in FIG. 3B and FIG. 8A can be manufactured.

FIG. 9E shows an example of the configuration of the semiconductor circuit device 10a manufactured by the method explained from FIG. 9A to FIG. 9D.

The semiconductor circuit device 10a has an upper part 36a of the connecting part 30a on the upper surface 74a of the substrate 70a. Cutting the first connecting part 90 forms the upper part 36a of the connecting part 30a. Moreover, the semiconductor circuit device 10a has a lower part 34a of the connecting part 30a on the side face 72a of the substrate 70a. The side face 72a of the substrate 70a is a cut face that is exposed by cutting the substrate 70 along the cutting line 88. The lower part 34a of the connecting part 30a is formed by cutting the second connecting part 92 along the cutting line 88.

Here, as shown in FIG. 9E, the upper part 36a of the connecting part 30a is preferably connected to the semiconductor element contained in the semiconductor circuit 60a by the wiring 50a. Furthermore, the lower part 34a of the connecting part 30a is preferably formed on the surface of the oxidizing film 82a.

As is clear from the above description, the semiconductor circuit device of the present embodiment can enlarge the area for the semiconductor circuit on the semiconductor circuit device. Furthermore, the semiconductor circuit device of the present embodiment can reduce the parasitic component such as a capacitance contained in the wire that causes the loss of electricity.

Although the present invention has been described by way of exemplary embodiments, it should be understood that those skilled in the art might make many changes and substitutions without departing from the spirit and the scope of the present invention, which is defined only by the appended claims.

What is claimed is:

1. A semiconductor circuit device comprising:
a substrate;
a semiconductor circuit formed on an upper surface of said substrate; and
a connecting part that is formed on a side face of said substrate, and said connecting part electrically connecting to said semiconductor circuit.

2. A semiconductor circuit device as claimed in claim 1, wherein said connecting part has an upper part on said upper surface of said substrate.

3. A semiconductor circuit device as claimed in claim 2, wherein said upper part of said connecting part is electrically connected to said semiconductor circuit.

4. A semiconductor circuit device as claimed in claim 1, wherein said connecting part has a lower part formed on a notch that is formed in said side face of said substrate.

5. A semiconductor circuit device as claimed in claim 4, wherein:
said connecting part further has an upper part on said upper surface of said substrate; and
said upper part of said connecting part is electrically connected to said lower part of said connecting part.

6. A semiconductor circuit device as claimed in claim 4, wherein said lower part is formed all over the surface of said notch.

7. A semiconductor circuit device as claimed in claim 4, wherein said lower part is formed on a part of a surface of said notch.

8. A semiconductor circuit device as claimed in claim 6, wherein said lower part is formed all over a bottom surface of said upper part that faces said substrate.

9. A semiconductor circuit device as claimed in claim 4, wherein said notch is formed on said side face of said substrate from a bottom surface through a top surface of said substrate.

10. A semiconductor circuit device as claimed in claim 4, wherein said upper part of said connecting part is formed by a material that is different to a material that forms said lower part of said connecting part.

11. A semiconductor circuit device as claimed in claim 1, wherein said connecting part is formed on a plurality of side faces of said substrate.

12. A semiconductor circuit device as claimed in claim 1, wherein a plurality of said connecting parts is formed on said side face of said substrate at a predetermined interval.

13. A semiconductor circuit device as claimed in claim 4, wherein said lower part of said connecting part is formed by gold.

14. A semiconductor circuit device as claimed in claim 1, wherein said connecting part of the semiconductor circuit device is electrically connected to another said connecting part that is formed on a side face of another said semiconductor circuit device.

15. A semiconductor circuit device as claimed in claim 4, wherein said notch has a half-cylindrical shape.

16. A semiconductor circuit device as claimed in claim 4, wherein said notch has a half-conical shape.

17. A semiconductor circuit device as claimed in claim 5, wherein the area of said upper part is larger than the area of said lower part that contacts with said upper part.

18. A semiconductor circuit device comprising:
a first semiconductor circuit device that includes:
a first substrate;
a first semiconductor circuit formed on an upper surface of said first substrate; and
a first connecting part that is formed on a side face of said first substrate, and said first connecting part electrically connecting to said first semiconductor circuit; and
a second semiconductor circuit device that includes:
a second substrate;
a second semiconductor circuit formed on an upper surface of said second substrate; and
a second connecting part that is formed on a side face of said second substrate, and said second connecting part electrically connecting to said second semiconductor circuit; wherein:
said first connecting part and said second connecting part are electrically connected to each other.

19. A semiconductor circuit device as claimed in claim 18, wherein: said side face of said first substrate of said first semiconductor circuit device and said side face of said second substrate of said second semiconductor circuit device are contacted with each other so that said first connecting part and said second connecting part are electrically connected to each other.

20. A semiconductor circuit device as claimed in claim 18, wherein:
said first connecting part is formed on a first notch provided in said side face of said first substrate; and
said second connecting part is formed on a second notch provided in said side face of said second substrate; and
said first notch and said second notch are filled by a conductive material when a said first connecting part and said second connecting part are contacted with each other.

21. A semiconductor circuit device as claimed in claim 18, wherein:
said first substrate has a concave part, in which said second semiconductor circuit device is installed, and said first connecting part is formed on a side face of said concave part; and
said first connecting part of said first semiconductor circuit device and said second connecting part of said second semiconductor circuit device are electrically connected to each other.

22. A method for manufacturing a semiconductor circuit device, comprising:
forming a first connecting part on an upper surface of a substrate;
forming a hole from a bottom surface through said upper surface of said substrate so that one end of said hole that faces said upper surface is covered by said first connecting part;
forming a second connecting part by forming a conductive material on a surface of said hole and a bottom surface of said first connecting part that faces said hole; and
cutting said substrate so that a part of said first connecting part and said second connecting part is exposed along a cutting face of said substrate.

23. A method as claimed in claim 22, wherein said forming said hole forms said hole in a half-cylindrical shape.

24. A method as claimed in claim 22, wherein said forming said hole forms said hole in a half-conical shape.

25. A method as claimed in claim 22, wherein said forming said first connecting part forms said first connecting part so that the area of said first connecting part becomes larger than the area of said second connecting part that contacts with said first connecting part.
